(19) United States
(12) Patent Application Publication
(10) Pub. No.: US 2013/0009161 A1
(43) Pub. Date: Jan. 10, 2013

(54) SEMICONDUCTOR DEVICE AND METHOD OF MANUFACTURING THE SAME, AND METHOD OF MANUFACTURING IMAGE DISPLAY DEVICE

(75) Inventor: Kazuo Himori, Kanagawa (JP)

(73) Assignee: SONY CORPORATION, Tokyo (JP)

(21) Appl. No.: 13/531,092

(22) Filed: Jun. 22, 2012

(30) Foreign Application Priority Data
Jul. 4, 2011 (JP) 2011-148016

(51) Int. Cl. H01L 51/10; H01L 51/40

(52) U.S. Cl. 257/60; 438/158; 438/164; 257/57; 257/E51.006

(57) ABSTRACT

There is provided a method of manufacturing a semiconductor device including: forming a gate electrode on a substrate ; forming a gate insulating layer of which a recessed portion is formed in a region in which a channel formation region is to be formed, on the substrate and the gate electrode; forming the channel formation region including an organic semiconductor material within the recessed portion based on a coating method; and forming source/drain electrodes on portions of the channel formation region from on the gate insulating layer.

### CROSS REFERENCES TO RELATED APPLICATIONS

The present application claims priority to Japanese Priority Patent Application JP 2011-148016 filed in the Japan Patent Office on Jul. 4, 2011, the entire content of which is hereby incorporated by reference.

### BACKGROUND

The present application relates to a semiconductor device and a method of manufacturing the same, and a method of manufacturing an image display device.

Currently, a field effect transistor (FET) including a thin film transistor (TFT) used in a variety of electronic equipment is configured of, for example, a channel formation region and source/drain electrodes formed in a substrate such as a silicon semiconductor substrate or a silicon semiconductor material layer, a gate insulating layer including SiO₂ formed on a surface of the substrate, and a gate electrode disposed to face the channel formation region with the gate insulating layer. In addition, such an FET is simply referred to as a top-gate type FET. Alternatively, the FET is configured by a gate electrode disposed on a support, a gate insulating layer disposed on the support including the gate electrode and including SiO₂, and a channel formation region and source/drain electrodes formed on the gate insulating layer. In addition, such an FET is simply referred to as a bottom-gate type FET. A very expensive device for manufacturing a semiconductor device is used to manufacture the FET having the structure described above, and it is thus necessary to reduce the manufacturing cost.

Among these, recently, electronic devices using a thin film including an organic semiconductor material have been actively developed, and in particular, organic electronics devices (which may be simply referred to hereinafter as organic devices) such as organic transistors are attracting attention. The ultimate goal of these organic devices may be to have a low cost, a light weight, flexibility, and high performance. When compared with inorganic materials of which silicon is a prime example, the organic semiconductor material (1) allows a large-sized organic device to be manufactured at a low cost at a low temperature in a simple process, (2) allows the organic device having the flexibility to be manufactured, and (3) allows performance or a physical property of the organic device to be controlled by modifying modules constituting the organic material to a desired form. The organic semiconductor material thus has such various advantages.

However, in the organic transistor, a channel formation region has an island-shaped planar surface, and is typically patterned by a combination of a photolithography technique and a wet etching method or a reactive ion etching (RIE) method. As a result, a step occurs between a substrate and the channel formation region in a top-gate type organic transistor, and a step also occurs between a gate insulating layer and the channel formation region in a bottom-gate type organic transistor. Source/drain electrodes are then formed on portions of the channel formation region from on the substrate in the top-gate type organic transistor, and are formed on portions of the channel formation region from on the gate insulating layer in the bottom-gate type organic transistor. Accordingly, a stepped cut may occur on the source/drain electrodes due to the step.

For example, a method of manufacturing a semiconductor device while avoiding an occurrence of problems such as the stepped cut of the source/drain electrodes caused by the step is well known in Japanese Laid-Open Patent Publication No. 2010-087063. The method of manufacturing a semiconductor device includes forming a gate insulating layer on a gate electrode formed on a substrate, forming source/drain electrodes to be spaced apart from each other on the gate insulating layer, forming a recessed portion to be recessed at a bottom surface of each of the source/drain electrodes in the gate insulating layer between the source/drain electrodes, and forming a semiconductor layer in contact with a portion of the bottom surface of each of the source/drain electrodes in the recessed portion.

### SUMMARY

The method of manufacturing a semiconductor device disclosed in Japanese Laid-Open Patent Publication No. 2010-087063 is an effective method for avoiding the occurrence of problems such as the stepped cut of the source/drain electrodes. However, when the channel formation region including an organic semiconductor material is formed by a coating method such as a spin coating method, the source/drain electrodes may be protruding obstacles, and it may be difficult for a solution of the organic semiconductor material to diffuse into and penetrate the recessed portion. In addition, in a state in which the recessed portion is formed, edges of the source/drain electrodes protrude upward in the recessed portion. Accordingly, for example, when pure water used for cleaning is spin-dried after wet etching is carried out, the protruding portions of the source/drain electrodes may be damaged by a centrifugal force or a wind pressure.

The present application thus provides a method of manufacturing a semiconductor device, a method of manufacturing an image display device to which the method of manufacturing a semiconductor device is applied, and a semiconductor device obtained by the method of manufacturing a semiconductor device that can reliably avoid an occurrence of problems such as the stepped cut of the source/drain electrodes and damaged source/drain electrodes and can also reliably form a channel formation region having an island-shaped planar surface (i.e., an element-isolated channel formation region).

According to a first aspect of the present application, there is provided a method of manufacturing a semiconductor device including: forming a gate electrode on a substrate ; forming a gate insulating layer of which a recessed portion is formed in a region in which a channel formation region is to be formed, on the substrate and the gate electrode; forming the channel formation region including an organic semiconductor material within the recessed portion based on a coating method; and forming source/drain electrodes on portions of the channel formation region from on the gate insulating layer.

According to a second aspect of the present application, there is provided a method of manufacturing a semiconductor device including: forming a recessed portion in a region of a base in which a channel formation region is to be formed; forming the channel formation region including an organic semiconductor material within the recessed portion based on a coating method; forming source/drain electrodes on portions of the channel formation region from on the base; forming a gate insulating layer on the channel formation region and the source/drain electrodes; and forming a gate electrode on the gate insulating layer over the channel formation region.

A method of manufacturing an image display device of the present application includes the method of manufacturing a semiconductor device of the first or second aspect of the present application.

According to the first aspect of the present application, there is provided a semiconductor device including: a gate electrode formed on a substrate; a gate insulating layer formed on the gate electrode and the substrate; a channel formation region disposed within a recessed portion formed in the gate insulating layer and including an organic semiconductor material; and source/drain electrodes formed on portions of the channel formation region from on the gate insulating layer, wherein a top surface of the channel formation region is recessed from a boundary between the gate insulating layer and the recessed portion toward a central portion of the recessed portion.

According to the second aspect of the present application, there is provided a semiconductor device including: a channel formation region disposed within a recessed portion formed in a base and including an organic semiconductor material; source/drain electrodes formed on portions of the channel formation region from on the base; a gate insulating layer formed on the source/drain electrodes and the channel formation region; and a gate electrode formed on the gate insulating layer, wherein a top surface of the channel formation region is recessed from a boundary between the base and the recessed portion toward a central portion of the recessed portion.

In the method of manufacturing a semiconductor device of the first or second embodiment of the present application and the method of manufacturing an image display device including the method of manufacturing a semiconductor device of the first or second embodiment of the present application, after a channel formation region formed of an organic semiconductor material is formed within a recessed portion disposed in a region of the gate insulating layer where the channel formation region is to be formed based on a coating method, source/drain electrodes are formed on portions of the channel formation region from on the gate insulating layer, or the channel formation region formed of an organic semiconductor material is formed within the recessed portion formed in a region of the base where the channel formation region is to be formed based on a coating method, source/drain electrodes are formed on portions of the channel formation region from on the base, and it is thus possible to surely avoid an occurrence of the problem such as the stepped cut of the source/drain electrodes and the damaged source/drain electrodes, and it is also possible to surely form the channel formation region having an island-shaped planar surface. In addition, it is possible to skip the photolithography process or the etching process for carrying out patterning (element isolation) on the channel formation region.

Additional features and advantages are described herein, and will be apparent from the following Detailed Description and the figures.

### BRIEF DESCRIPTION OF THE FIGURES

FIGS. 1A and 1B are a partial cross-sectional diagram schematically illustrating a semiconductor device of a first embodiment and a cross-sectional diagram schematically illustrating an enlarged portion of a channel formation region or source/drain electrodes, respectively;

FIGS. 2A to 2C are partial cross-sectional diagrams of a substrate or the like schematically illustrating a method of manufacturing a semiconductor device of the first embodiment;

FIGS. 3A and 3B are partial cross-sectional diagrams of the substrate or the like schematically illustrating the method of manufacturing a semiconductor device of the first embodiment following FIG. 2C;

FIGS. 4A and 4B are a partial cross-sectional diagram schematically illustrating a semiconductor device of a second embodiment and a cross-sectional diagram schematically illustrating an enlarged portion of a channel formation region or source/drain electrodes, respectively;

FIGS. 5A to 5C are partial cross-sectional diagrams of a base or the like schematically illustrating a method of manufacturing a semiconductor device of the second embodiment; and

FIGS. 6A and 6B are partial cross-sectional diagrams of the base or the like schematically illustrating the method of manufacturing a semiconductor device of the second embodiment following FIG. 5C.

### DETAILED DESCRIPTION

Hereinafter, preferred embodiments of the present disclosure will be described in detail with reference to the appended drawings. Note that, in this specification and the appended drawings, structural elements that have substantially the same function and structure are denoted with the same reference numerals, and repeated explanation of these structural elements is omitted.

Hereinafter, embodiments of the present application will be described with reference to drawings, however, the present application is not limited to the embodiments, and various values or materials of the embodiments are merely illustrative. Further, the description will be made in the following order.

1. Semiconductor device and manufacturing method thereof according to first and second embodiments of present application, method of manufacturing image display device, and general description

2. First embodiment (semiconductor device and manufacturing method thereof according to first embodiment of present application, and method of manufacturing image display device)

3. Second embodiment (semiconductor device and manufacturing method thereof according to second embodiment of present application, and method of manufacturing image display device), and so forth

[Semiconductor Device and Manufacturing Method Thereof According to First and Second Embodiments of Present Application, Method of Manufacturing Image Display Device, and General Description]

In a method of manufacturing a semiconductor device of the first embodiment of the present application or a method of manufacturing an image display device of the present application including the method of manufacturing the semiconductor device of the first embodiment of the present application, it is preferable that wettability of a recessed portion surface of a gate insulating layer be better than wettability of a region of the gate insulating layer other than the recessed portion. In addition, in a method of manufacturing a semiconductor device of the second embodiment of the present application or a method of manufacturing an image display device of the present application including the method of manufacturing a semiconductor device of the second embodiment of the present application, it is preferable that wettability of a recessed portion surface of a base be better than wettability of a region of the base other than the recessed portion. In particular, a contact angle θ₁ between water and the recessed portion surface of the gate insulating layer or the base is, for example, 1° to 50°, and a contact angle θ₂ between water and a region of the gate insulating layer or the base other than the recessed portion is, for example, 70° to 100°.

In the method of manufacturing a semiconductor device of the first embodiment of the present application including the preferred forms described above, the method of manufacturing an image display device of the present application including the method of manufacturing a semiconductor device of the first embodiment of the present application, the method of manufacturing a semiconductor device of the second embodiment of the present application, or the method of manufacturing an image display device of the present application including the method of manufacturing a semiconductor device of the second embodiment of the present application, it is preferable that the recessed portion be formed based on a plasma etching method, in particular, for example, an RIE method. When the recessed portion is formed based on the plasma etching method, oxygen atoms are attached to the recessed portion surface after etching. Since the recessed portion surface is chemically modified, the wettability of the recessed portion surface is better than the wettability of an insulating layer or a base other than the recessed portion.

In the semiconductor device according to the first or second embodiment of the present application, it is preferable that an angle formed between a top surface of a channel formation region in a boundary between the recessed portion and the gate insulating layer or the base and a top surface of the gate insulating layer or the base be 1° to 10°.

In the method of manufacturing a semiconductor device of the first embodiment of the present application including the preferred forms described above, the method of manufacturing an image display device of the present application including the method of manufacturing a semiconductor device of the first embodiment of the present application, the method of manufacturing a semiconductor device of the second embodiment of the present application, or the method of manufacturing an image display device of the present application including the method of manufacturing a semiconductor device of the second embodiment of the present application, and the semiconductor device of the first or second embodiment of the present application (these may be collectively referred to hereinafter as simply the present application), a side wall of the recessed portion may be vertical, may be provided with a so-called forward taper, or may be provided with a so-called backward taper.

As the image display device in the method of manufacturing an image display device of the present application, a liquid crystal display device, an image display device having organic electroluminescence elements, an image display device having microcapsule-type electrophoretic display elements, and a plasma display device may be employed. In addition, for example, the image display device may be applied to various image display devices such as so-called desktop-type personal computers, notebook-type personal computers, mobile-type personal computers, personal digital assistants (PDAs), cellular phones, gaming machines, electronic books, electronic papers such as electronic newspapers, signboards, posters, bulletin boards such as black boards, copying machines, rewritable papers replacing printer papers, electronic calculators, display portions of home appliances, card display portions of point cards or the like, electronic advertisements, electronic POPs, and so forth.

In the present application, as an organic semiconductor material, polythiophene, poly-3-hexylthiophene [P3HT] in which a hexyl group is introduced into polythiophene, pentacene[2,3,6,7-dibenzanthracene], derivatives of pentacene [triisopropylsilylethynyl(TIPS)-pentacene, and so forth], dioxa anthanthrane-based compound containing perixanthenoxanthene and so forth, polyanthracene, naphthacene, hexacene, heptacene, dibenzopentacene, tetrabenzopentacene, chrysene, perylene, coronene, terylene, ovalene, quaterrylene, circumanthracene, benzopyrene, dibenzopyrene, triphenylene, polypyrrole, polyaniline, polyacetylene, polydiacetylene, polyphenylene, polyfuran, polyindole, polyvinylcarbazole, polyselenophene, polytellurophene, polyisothianaphthene, polycarbazole, polyphenylene sulphide, polyphenylene vinylene, polyvinylene sulphide, polythienylene vinylene, polynaphthalene, polypyrene, polyazulene, phthalocyanine represented by copper phthalocyanine, merocyanine, hemicyanine, polyethylenedioxythiophene, pyridazine, naphthalene tetracarboxylic acid dimide, poly(3,4-ethylenedioxythiophene)/polystyrenesulfonic acid [PEDOT/PSS], and quinacridone may be employed. Alternatively, as the organic semiconductor material, a compound selected from the group including a condensed polycyclic aromatic compound, a porphyrin based derivative, a phenylvinylidene based conjugated oligomer, and a thiophene-based conjugated oligomer may be employed. In particular, for example, condensed polycyclic aromatic compounds such as acene-based molecules (pentacene, tetracene, and so forth), porphyrin based molecules, and (phenylvinylidene based or thiophene based) conjugated oligomers may be employed.

Alternatively, as the organic semiconductor material, for example, porphyrin, 4,4′-biphenyldithiol (BPDT), 4,4′-diisocyanobiphenyl, 4,4′-diisocyano-p-terphenyl, 2,5-bis(5′-thioacetyl-2′-thiophenyl)thiophene, 2,5-bis(5′-thioacetoxyl-2′-thiophenyl)thiophene, 4,4′-diisocyanophenyl, benzidine(biphenyl-4,4′-diamine), tetracyanoquinodimethane (TCNQ), tetrathiafulvalene (TTF)-TCNQ complex, bisethylenetetrathiafulvalene (BEDTTTF)-perchloric acid complex, BEDTTTF-iodine complex, charge transfer complex represented by TCNQ-iodine complex, biphenyl-4,4′-dicarboxylic acid, 1,4-di(4-thiophenylacetylenyl)-2-ethylbenzene, 1,4-di(4-isocyanophenylacetylenyl)-2-ethylbenzene, dendrimer, a fullerene such as C60, C70, C76, C78, or C84, 1,4-di(4-thiophenylethynyl)-2-ethylbenzene, 2,2″-dihydroxy-1, 1′:4′,1″-terphenyl, 4,4′ -biphenyldiethanal, 4,4′-biphenyldiol, 4,4′-biphenyldiisocyanate, 1,4-diacetylbenzene, diethylbiphenyl-4,4′-dicarboxylate, benzo[1,2-c; 3,4-c′; 5,6-c″]tris[1,2]dithiol-1,4,7-trithione, alpha-sexithiophene, tetrathiotetracene, tetraselenotetracene, tetratellurotetracene, poly(-alkylthiophene), poly(3-thiophene-β-ethanesulfonic acid), poly(N-alkylpyrrole) poly(3-alkylpyrrole), poly(3,4-dialkylpyrrole), poly(2,2′-thienylpyrrole), and poly(dibenzothiophene sulphide) may be employed.

A polymer may be included in the channel formation region (organic semiconductor material layer) as necessary. The polymer may be dissolved in an organic solvent. In particular, as the polymer (organic binder, binder), polystyrene, polyalphamethylstyrene, or polyolefin may be employed. In addition, in some cases, an additive (e.g., a so-called doping material such as n-type impurities or p-type impurities) may be added.

As a solvent for preparing the organic semiconductor material solution, aromatics such as toluene, xylene, mesitylene, and tetralin; ketones such as cyclopentanone, and cyclohexanone; and hydrocarbons such as decalin may be employed. Above all, it is preferable that solvents having a relatively high boiling point such as mesitylene, tetralin, and decalin be used in terms of transistor characteristics and also in terms of preventing the organic semiconductor material from being rapidly dried at the time of forming the channel formation region.

As a coating method for forming the channel formation region, various printing methods such as a screen printing method, an inkjet printing method, an offset printing method, a reverse offset printing method, a gravure printing method, a gravure offset printing method, a relief printing method, a flexo printing method, a microcontact method; a spin coating method; various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit coater method, a slit orifice coater method, a cap coat method, a calendar coater method, a casting method, a capillary coater method, a bar coater method, a dipping method; a spray method; a method using a dispenser; and a method of coating a liquid material such as a stamp method may be employed. In addition, after coating, the remaining organic semiconductor material solution may be removed by means of a squeegee.

As a material for forming a gate electrode and source/drain electrodes, metals such as platinum (Pt), gold (Au), palladium (Pd), chromium (Cr), molybdenum (Mo), nickel (Ni), aluminum (Al), silver (Ag), tantalum (Ta), tungsten (W), copper (Cu), titanium (Ti), indium (In), tin (Sn), iron (Fe), cobalt (Co), zinc (Zn), magnesium (Mg) or alloys including these metallic elements, conductive particles including these metals, conductive particles of alloys including these metals, indium tin oxides (ITO), conductive materials such as polysilicon containing impurities, and so forth may be employed, and a stacked structure of layers including these elements (e.g., MoOₓ/Au, CuO/Au) may also be employed. In addition, as a material for forming the gate electrode and the source/drain electrodes, a PEDOT/PSS or an organic material (conductive high molecules) such as polyaniline may be employed. The material for forming the gate electrode and the source/drain electrodes may be the same material or different materials.

As a method of forming the gate electrode and the source/drain electrodes, although also depending on the material for forming the electrodes, any one of the coating methods listed above, a physical vapor deposition (PVD) method, a pulse laser deposition (PLD) method, an arc discharge method, various chemical vapor deposition (CVD) methods including metal organic CVD (MOCVD), a lift off method, a shadow mask method, and a plating method such as an electrolytic plating method, a non-electrolytic plating method, and a patterning technique may be combined as necessary. In addition, as the PVD method, (a) various evaporation methods such as an electron beam heating method, a resistance heating method, a flash evaporation method, a method of heating a crucible, (b) a plasma deposition method, (c), various sputtering methods such as a dipole sputtering method, a direct current sputtering method, a direct current magnetron sputtering method, a high-frequency sputtering method, a magnetron sputtering method, an ion beam sputtering method, a bias sputtering method, (d) a direct current (DC) method, a radio frequency (RF) method, a multi cathode method, an activation reaction method, an electric field deposition method, and various ion plating methods such as a high frequency ion plating method and a reactive ion plating method may be employed. When a resist pattern is formed, for example, a resist material is coated to form a resist layer, and a photolithography technique, a laser lithography technique, an electron beam lithography technique, or an X-beam lithography technique is then used to pattern the resist layer. A resist transfer method or the like may be used to form the resist pattern. When the gate electrode and the source/drain electrodes are formed based on an etching method, a dry etching method or a wet etching method may be employed, and ion milling or RIE may be employed as the dry etching method, for example. In addition, the gate electrode and the source/drain electrodes may be formed based on a laser abrasion method, a mask deposition method, a laser transfer method, and so forth. Alternatively, the gate electrode and the source/drain electrodes may be formed based on a printing method. Since a surface of a channel formation region and a surface of an insulating layer around the channel formation region are very flat, that is, there is no step, a stepped cut thus does not occur even when the source/drain electrodes are formed based on the printing method.

The gate insulating layer may be single-layered or multi-layered. As a material for forming the gate insulating layer, not only a silicon oxide based material and an inorganic insulating material illustrated by a metal oxide high-k insulating film such as a silicon nitride (SiNy), aluminum oxide (Al₂O₃) or HfO₂ but also an organic insulating material (organic polymer) illustrated by polymethylmethacrylate (PMMA), polyvinylphenol (PVP), polyvinyl alcohol (PVA), polyimide, polycarbonate (PC), polyethylene terephthalate (PET), polystyrene, N-2(aminoethyl) 3-aminopropyl trimethoxysilane (AEAPTMS), 3-mercaptopropyl trimethoxysilane (MPTMS), a silanol derivative such as octadecyl trichlorosilane (OTS) (a silane coupling agent), octadecanethiol, and a straight chain hydrocarbon having a functional group capable of being coupled at one end of dodecyl isocyanate may be employed, and a combination thereof may also be used. Here, as the silicon oxide based material, a silicon oxide (SiO_{X}), BPSG, PSG, BSG, AsSG, PbSG, silicon oxynitride (SiON), a spin-on-glass (SOG), and a low-k SiO₂ based material (e.g., polyarylether, cycloperfluorocarbon polymer and benzo cyclobutene, cyclic fluorine resin, polytetrafluoroethylene, arylether fluoride, polyimide fluoride, amorphous carbon, and organic SOG) may be employed.

As a method of forming the gate insulating layer, besides the coating methods listed above, a combination of any one of a lift off method, a sol-gel method, an electrodeposition method and a shadow mask method, and a patterning technique may be employed as necessary.

In the method of manufacturing a semiconductor device of the first embodiment of the present application or the method of manufacturing an image display device including the method of manufacturing a semiconductor device of the first embodiment of the present application, the substrate may include a silicon oxide based material (e.g., SiO_{X} or SOG), a silicon nitride (SiN_{Y}), and a metal oxide high-k insulating film such as aluminum oxide (Al₂O₃) or HfO₂. When the substrate is formed of the materials, the substrate may be formed on a support (or above the support) properly selected from materials listed below. That is, as the support or a substrate other than the substrate described above, a plastic film, a plastic sheet, or a plastic substrate having flexibility including an organic polymer illustrated by polymethyl methacrylate (polymethacrylic acid methyl (PMMA)) or PVA, PVP, polyether sulfone (PES), polyimide, PC, PET, polyethylene naphthalate (PEN), or mica may be employed. When the substrate formed of the high-molecular material such as the organic polymer having flexibility, for example, it is possible to assemble an electronic device or a semiconductor device with a display device or electronic equipment having a curved surface shape. Alternatively, as the substrate, various glass substrates, various glass substrates on which an insulating film is formed, a quartz substrate, a quartz substrate on which an insulating film is formed, a silicon substrate on which an insulating film is formed, a sapphire substrate, a metallic substrate formed of various alloys such as stainless steel or various metals may be employed. For the support having an electrically insulating property, any material listed above may be properly selected. Also, as the support, a conductive substrate (a substrate formed of a metal such as gold or aluminum, a substrate formed of high-orientation graphite, or a stainless steel substrate) may be employed. In addition, depending on the configuration and structure of the semiconductor device, the semiconductor device may be formed on the support. However, the support may also be formed of the material listed above.

In the method of manufacturing a semiconductor device of the second embodiment of the present application or the method of manufacturing an image display device including the method of manufacturing a semiconductor device of the second embodiment of the present application, the base may be formed of the material for forming the gate insulating layer described above, and may also be single-layered or multi-layered. The method of forming the base may also be the same as the method of forming the gate insulating layer described above. The base may be formed on the support (or above the support) described above.

When the semiconductor device of the present application is applied to display devices or various electronic equipment and used, it may be used as a monolithic integrated circuit integrated with a number of semiconductor devices, and may also be used as a discrete part after the semiconductor devices are individually diced. In addition, the semiconductor device may be sealed with a resin.

### First Embodiment

The first embodiment relates to a semiconductor device and a method of manufacturing the same in accordance with the first embodiment of the present application, and a method of manufacturing an image display device including the method of manufacturing the same in accordance with the first embodiment of the present application.

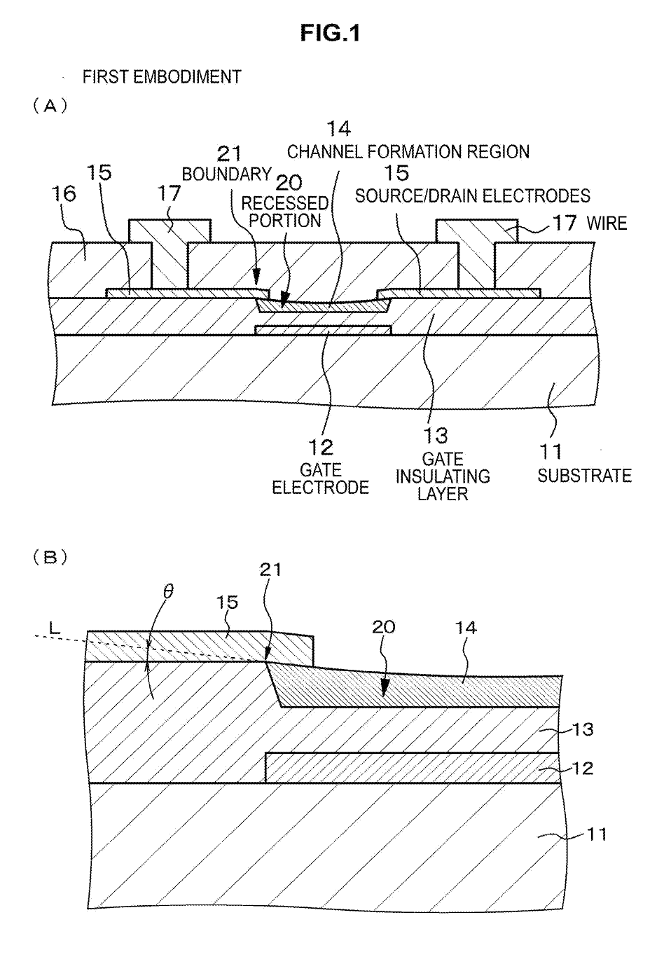

The semiconductor device of the first embodiment is a bottom gate-top contact type thin film transistor (TFT). A partial cross-sectional diagram thereof is schematically illustrated in FIG. 1A. As shown in FIG. 1B of the cross-sectional diagram schematically illustrating an enlarged portion of a channel formation region or source/drain electrodes, the semiconductor device includes (A) a gate electrode 12 formed on a substrate 11, (B) a gate insulating layer 13 formed on the gate electrode 12 and the substrate 11, (C) a channel formation region 14 formed within a recessed portion 20 formed in the gate insulating layer 13 and including an organic semiconductor material, and (D) source/drain electrodes 15 formed on portions of the channel formation region 14 from on the gate insulating layer 13.

A top surface of the channel formation region 14 is recessed from a boundary 21 between the gate insulating layer 13 and the recessed portion 20 toward a central portion of the recessed portion 20. In particular, an angle θ between the top surface of the channel formation region 14 and the top surface of the gate insulating layer 13 in the boundary 21 between the gate insulating layer 13 and the recessed portion 20 is 1° to 10°, and is preferably 4°. In addition, a virtual extension line of the top surface of the channel formation region 14 in the boundary 21 between the gate insulating layer 13 and the recessed portion 20 is illustrated with a dotted line L in FIG. 1B.

In the first embodiment, the substrate 11 is a PES substrate, the gate electrode 12 and the source/drain electrodes 15 are gold thin films, the channel formation region 14 is formed of a derivative of pentacene [triisopropylsilylethynyl (TIPS)-pentacene], and the gate insulating layer 13 is formed of polyvinylphenol (PVP).

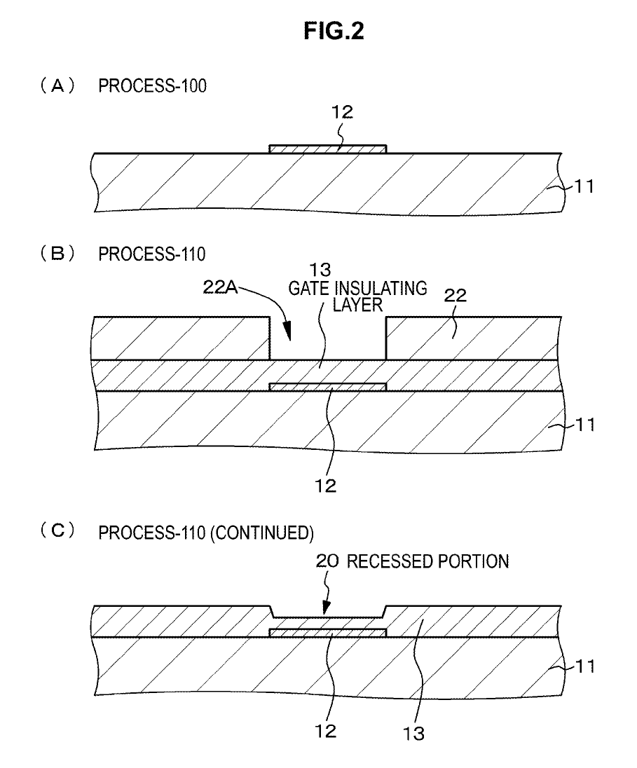

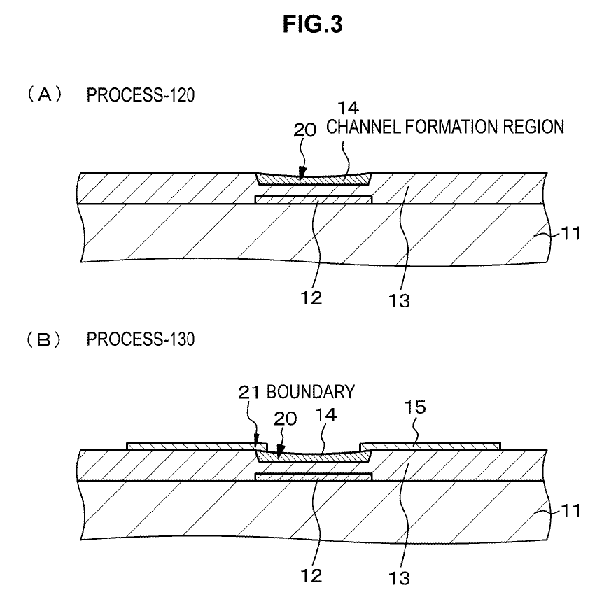

Hereinafter, the method of manufacturing a semiconductor device of the first embodiment and the method of manufacturing an image display device will be described with reference to FIGS. 2A to 2C and FIGS. 3A and 3B schematically illustrating partial cross-sectional diagrams of the substrate or the like.

[Process-100]

First, the gate electrode 12 is formed on the substrate 11. In particular, a Ti layer as an adhesive layer and an Au layer as the gate electrode 12 are sequentially formed on the substrate 11 by a vacuum evaporation method. The Au layer and the Ti layer are then patterned based on a photolithography technique and an etching technique, thereby obtaining the gate electrode 12 formed of an Au layer (see FIG. 2A). In addition, the adhesive layer is not illustrated in the drawings.

[Process-110]

The gate insulating layer 13 having the recessed portion 20 is then formed in a region in which the channel formation region 14 is to be formed on the substrate 11 and the gate electrode 12. In particular, a mixed solution of PVP and melamine as a curing agent is coated on an entire surface of the obtained structure based on a spin coating method, and then drying and baking are carried out, thereby obtaining the gate insulating layer 13. A resist layer 22 having an opening 22A is then formed in a region in which a channel formation region is to be formed (see FIG. 2B). After the recessed portion 20 is formed based on a plasma etching method, more specifically, for example, an RIE method, the resist layer 22 is removed (see FIG. 2C). The wettability of the surface of the recessed portion 20 of the gate insulating layer 13 is better than wettability of a region of the gate insulating layer 13 other than the recessed portion 20. In particular, a contact angle θ₁ between water and the surface of the recessed portion 20 formed in the gate insulating layer 13 is about 40°, and a contact angle θ₂ between water and the region of the gate insulating layer 13 other than the recessed portion 20 is about 70°. In addition, a side wall of the recessed portion 20, although also depending on conditions of the RIE, may be vertical, may be provided with a so-called taper (see FIG. 1B), and may also be provided with a so-called backward taper.

[Process-120]

The channel formation region 14 formed of an organic semiconductor material is then formed within the recessed portion 20 based on a coating method. In particular, an organic semiconductor material solution in which TIPS-pentacene is dissolved in xylene is coated on an entire surface of the obtained structure based on the spin coating method. The wettability of the surface of the recessed portion 20 of the gate insulating layer 13 is better than the wettability of the region of the gate insulating layer 13 other than the recessed portion 20. For this reason, the organic semiconductor material solution remains within the recessed portion 20, but does not remain on the region of the gate insulating layer 13 other than the recessed portion 20. The organic semiconductor material is then dried and baked, thereby forming the channel formation region 14 (see FIG. 3A). In addition, drying and baking may also be carried out after the remaining organic semiconductor material solution is removed by a squeegee or the like. Drying and baking the organic semiconductor material allows the top surface of the channel formation region 14 to be recessed from the boundary between the gate insulating layer 13 and the recessed portion 20 toward a central portion of the recessed portion 20.

[Process-130]

Next, the source/drain electrodes 15 are formed on portions of the channel formation region 14 from on the gate insulating layer 13. In particular, a Ti layer as an adhesive layer and an Au layer as source/drain electrodes are sequentially formed on the gate insulating layer 13 and the channel formation region 14 by a vacuum evaporation method. The Au layer and the Ti layer are then patterned based on the photolithography technique and the etching technique, thereby obtaining the source/drain electrodes 15 formed of the Au layer (see FIG. 3B). In addition, the adhesive layer is not illustrated in the drawings.

[Process-140]

Next, an insulating layer 16 formed of SiO₂ is formed on an entire surface of the obtained structure based on a well-known method, openings are formed in portions of the insulating layer 16 above the gate electrode 12 and the source/drain electrodes 15, a wire material layer is formed on the insulating layer 16 including the openings, and the wire material layer is patterned, thereby forming a wire (not shown) connected to the gate electrode 12 and a wire 17 connected to the source/drain electrodes 15. It is thus possible to obtain the semiconductor device that is a bottom gate-top contact type of the first embodiment shown in FIG. 1A. Alternatively, the image display device having the semiconductor device of the first embodiment can be obtained. In addition, subsequent to this process, an image display portion (in particular, for example, the image display portion having an organic electroluminescence element, a microcapsule type electrophoretic display element, or a semiconductor light emitting element) may be formed on or above the semiconductor device based on a well-known method when the image display device is manufactured.

In the method of manufacturing the semiconductor device of the first embodiment, after the channel formation region 14 formed of the organic semiconductor material is formed within the recessed portion 20 disposed in a region of the gate insulating layer 13 in which the channel formation region 14 is to be formed based on a coating method, the source/drain electrodes 15 are formed on portions of the channel formation region 14 from on the gate insulating layer 13. Therefore, it is possible to reliably avoid an occurrence of problems such as the stepped cut of the source/drain electrodes 15 and the damaged source/drain electrodes 15, and it is also possible to reliably form the channel formation region 14 having an island-shaped planar surface. In addition, it is possible to skip the photolithography process or the etching process for carrying out patterning (element isolation) on the channel formation region 14.

### Second Embodiment

The second embodiment relates to a method of manufacturing a semiconductor device of the second embodiment of the present application and a method of manufacturing an image display device including the method of manufacturing a semiconductor device of the second embodiment of the present application.

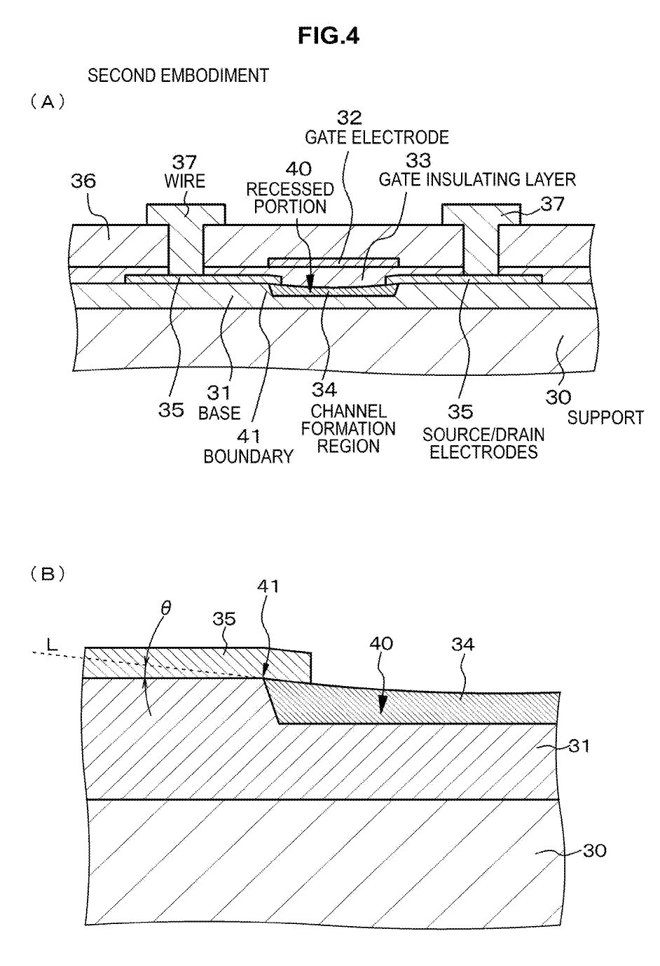

The semiconductor device of the second embodiment is a top gate-top contact type TFT. A partial cross-sectional diagram thereof is schematically illustrated in FIG. 4A. As shown in FIG. 4B of the cross-sectional diagram schematically illustrating an enlarged portion of a channel formation region or source/drain electrodes, the semiconductor device includes (A) a channel formation region 34 disposed within a recessed portion 40 formed in a base 31 and including an organic semiconductor material, (B) source/drain electrodes 35 formed on portions of the channel formation region 34 from on the base 31, (C) a gate insulating layer 33 formed on the source/drain electrodes 35 and the channel formation region 34, and (D) a gate electrode 32 formed on the gate insulating layer 33.

A top surface of the channel formation region 34 is recessed from a boundary 41 between the gate insulating layer 33 and the recessed portion 40 toward a central portion of the recessed portion 40. In particular, an angle 0 between a top surface of the channel formation region 34 and a top surface of the base 31 in the boundary 41 between the base 31 and the recessed portion 40 is 1° to 10°, and is preferably 4°. In addition, a virtual extension line of the top surface of the channel formation region 34 in the boundary 41 between the base 31 and the recessed portion 40 is illustrated with a dotted line L in FIG. 4B.

In the second embodiment, the base 31 is formed of PVP and is formed on a support 30 formed of PES, the gate electrode 32 and the source/drain electrodes 35 are formed of a gold thin film, the channel formation region 34 is formed of a derivative of pentacene [TIPS-pentacene], and the gate insulating layer 33 is formed of PVP.

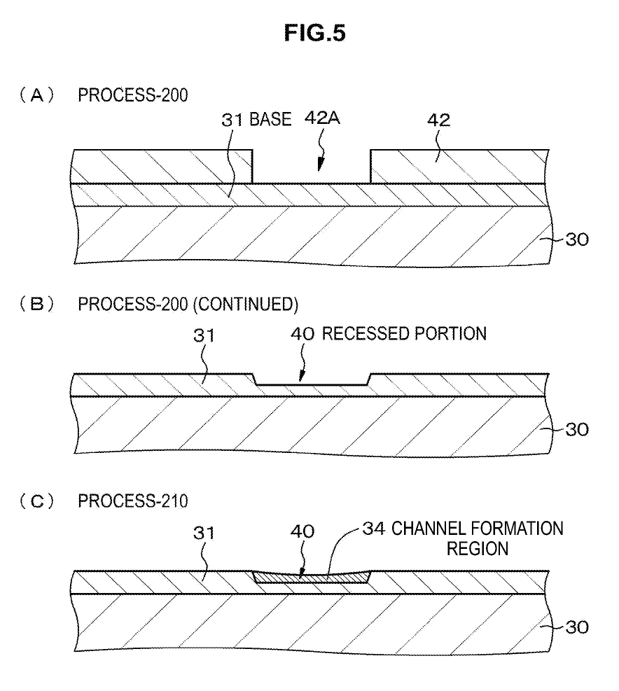

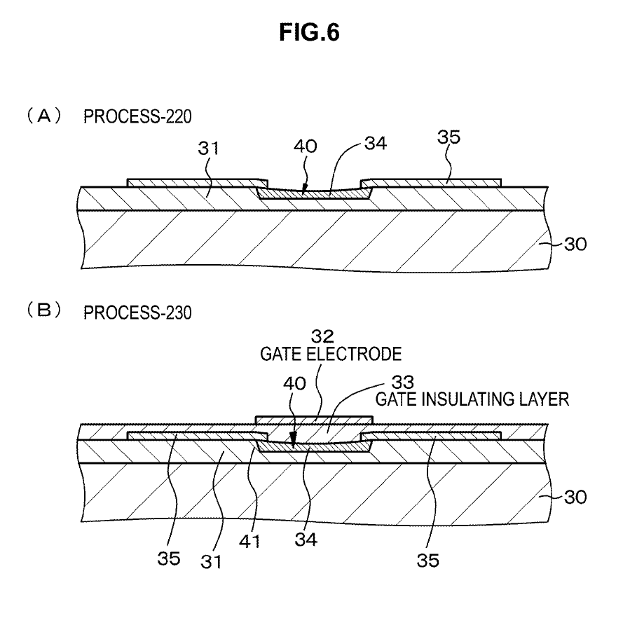

Hereinafter, the method of manufacturing a semiconductor device of the second embodiment and the method of manufacturing an image display device will be described with reference to FIGS. 5A to 5C and FIGS. 6A and 6B schematically illustrating partial cross-sectional diagrams of the base or the like.

[Process-200]

First, the recessed portion 40 is formed in a region of the base 31 in which a channel formation region 34 is to be formed. In particular, a mixed solution of PVP and melamine as a curing agent is coated on the support 30 based on a spin coating method, and then drying and baking are carried out, thereby obtaining the base 31. A resist layer 42 having openings 42A is then formed in a region in which the channel formation region is to be formed (see FIG. 5A). After the recessed portion 40 is formed based on a plasma etching method, in particular, for example, an RIE method, the resist layer 42 is removed (see FIG. 5B). The wettability of the surface of the recessed portion 40 formed in the base 31 is better than the wettability of the region of the base 31 other than the recessed portion 40. In particular, a contact angle θ₁ between water and the surface of the recessed portion 40 formed in the base 31 is about 40°, and a contact angle θ₂ between water and the region of the base 31 other than the recessed portion 40 is about 70°. In addition, a side wall of the recessed portion 40, although also depending on conditions of the RIE, may be vertical, may be provided with a so-called forward taper (see FIG. 5B), and may also be provided with a so-called backward taper.

[Process-210]

The channel formation region 34 formed of an organic semiconductor material is then formed within the recessed portion 40 based on a coating method. In particular, an organic semiconductor material solution in which TIPS-pentacene is dissolved in xylene is coated on an entire surface of the obtained structure based on the spin coating method. The wettability of the surface of the recessed portion 40 of the base 31 is better than the wettability of the region of the base 31 other than the recessed portion 40. For this reason, the organic semiconductor material solution remains within the recessed portion 40, but does not remain on the region of the base 31 other than the recessed portion 40. The organic semiconductor material is then dried and baked, thereby forming the channel formation region 34 (see FIG. 5C). In addition, drying and baking may also be carried out after the remaining organic semiconductor material solution is removed by a squeegee or the like. Drying and baking the organic semiconductor material allows the top surface of the channel formation region 34 to be recessed from the boundary between the gate insulating layer 33 and the recessed portion 40 toward a central portion of the recessed portion 40.

[Process-220]

Next, the source/drain electrodes 35 are formed on portions of the channel formation region 34 from on the base 31. In particular, a Ti layer as an adhesive layer and an Au layer as source/drain electrodes are sequentially formed on the base 31 and the channel formation region 34 by a vacuum evaporation method. The Au layer and the Ti layer are then patterned based on the photolithography technique and the etching technique, thereby obtaining the source/drain electrodes 35 formed of the Au layer (see FIG. 6A). In addition, the adhesive layer is not illustrated in the drawings.

[Process-230]

Next, the gate insulating layer 33 is formed on the channel formation region 34 and the source/drain electrodes 35, and the gate electrode 32 is formed on the gate insulating layer 33 over the channel formation region 34. In particular, a mixed solution of PVP and melamine as a curing agent is coated on an entire surface of the obtained structure based on a spin coating method, and then drying and baking are carried out, thereby obtaining the gate insulating layer 33. The gate electrode 32 is then formed on the gate insulating layer 33. In particular, a Ti layer as an adhesive layer and an Au layer as the gate electrode 32 are sequentially formed on the gate insulating layer 33 by a vacuum evaporation method. The Au layer and the Ti layer are then patterned based on a photolithography technique and an etching technique, thereby obtaining the gate electrode 32 formed of the Au layer (see FIG. 6B). In addition, the adhesive layer is not illustrated in the drawings.

[Process-240]

Next, an insulating layer 36 formed of SiO₂ is formed on an entire surface of the obtained structure based on a well-known method, openings are formed in portions of the gate insulating layer 33 and the insulating layer 36 above the gate electrode 32 and the source/drain electrodes 35, a wire material layer is formed on the insulating layer 36 including the openings, and the wire material layer is patterned, thereby forming a wire (not shown) connected to the gate electrode 32 and wires 37 connected to the source/drain electrodes 35. It is thus possible to obtain the semiconductor device that is a top gate-top contact type of the second embodiment shown in FIG. 4A. Alternatively, the image display device having the semiconductor device of the second embodiment can be obtained. In addition, subsequent to this process, an image display portion (in particular, for example, the image display portion having an organic electroluminescence element, a microcapsule-type electrophoretic display element, or a semiconductor light emitting element) may be formed on or above the semiconductor device based on a well-known method when the image display device is manufactured.

In the method of manufacturing a semiconductor device of the second embodiment, after the channel formation region 34 formed of the organic semiconductor material is formed within the recessed portion 40 disposed in a region of the base 31 in which the channel formation region 34 is to be formed based on a coating method, the source/drain electrodes 35 are formed on portions of the channel formation region 34 from on the base 31. Therefore, it is possible to reliably avoid an occurrence of problems such as the stepped cut of the source/drain electrodes 35 and the damaged source/drain electrodes 35, and it is also possible to reliably form the channel formation region 34 having an island-shaped planar surface. In addition, it is possible to skip the photolithography process or the etching process for carrying out patterning (element isolation) on the channel formation region 34.

Although the present application has been described based on the preferred embodiments, the present application is not limited to these embodiments. The structure or configuration, formation conditions, and manufacturing conditions of the semiconductor device are merely illustrative, and may be modified as appropriate. For example, when the semiconductor device of the present application is applied to display devices or various electronic equipments and used, it may be used as a monolithic integrated circuit of which the substrate, the base, the support, or a support member is integrated with a number of semiconductor devices, and may also be used as a discrete part after the semiconductor devices are individually diced. In addition, the semiconductor device may be sealed with a resin.

Although the gate insulating layer or the base on which the recessed portion is to be formed is a single layer in the embodiments, the gate insulating layer or the base may have a two-layered structure of which etching rates are different at the time of carrying out etching by means of the RIE method, and the recessed portion having a desired depth can thus be formed. That is, the recessed portion may be formed on an upper layer of the gate insulating layer or the base having the two-layered structure to expose a lower layer. The source/drain electrodes may be formed on the gate insulating layer or the base, or the channel formation region by a vacuum evaporation method while a portion of the channel formation region, the gate insulating layer or the base is covered with a hard mask, and the source/drain electrodes can thus be formed without a photolithography process. The gate electrode can also be formed in a similar way. In addition, the gate electrode or the source/drain electrodes may be formed based on a so-called lift off method. Further, the gate electrode or the source/drain electrodes may be formed by a printing method. Since the surface of the channel formation region and the surface of the insulating layer around the channel formation region are very flat, that is, there is no step, a stepped cut thus does not occur even when the source/drain electrodes are formed based on the printing method.

The structure of the semiconductor device of the present application may be applied to an electronic device, for example, a light emitting element. That is, the light emitting element (an organic light emitting element, and an organic light emitting transistor) of which an active layer emits light by applying a voltage to a control electrode, a first electrode and a second electrode can be configured. A current flowing from the first electrode toward the second electrode is controlled by the voltage applied to the control electrode in the electronic device. In addition, the control electrode corresponds to the gate electrode of the semiconductor device of the present application, the first and second electrodes correspond to the source/drain electrodes of the semiconductor device of the present application, and the active layer corresponds to the channel formation region of the semiconductor device of the present application. An insulating layer is formed between the control electrode and the active layer, and corresponds to the gate insulating layer of the semiconductor device of the present application. Here, the organic semiconductor material for forming the active layer in the light emitting element has a light emitting function based on accumulation of electric charges by means of modulation based on the voltage applied to the control electrode or recombination of injected electrons and positive holes. As the organic semiconductor material for forming the active layer, an organic semiconductor material having a p-type conductivity or a non-doped organic semiconductor material may be broadly used. In the light emitting element (an organic light emitting transistor) having the active layer formed of the organic semiconductor material having the p-type conductivity, the light emitting intensity is in proportion to an absolute value of the current flowing from the first electrode to the second electrode, and may be modulated by the voltage applied to the control gate and the voltage applied between the first and second electrodes. In addition, whether the electronic device acts as an FET or a light emitting element depends on a state of the voltages (bias) applied to the first and second electrodes. First, the bias is applied in a range of which electrons are not injected into the second electrode and then the control electrode is modulated, and the current thus flows from the first electrode toward the second electrode. This is the transistor operation. On the other hand, when the bias is increased to the first and second electrodes while the holes are sufficiently accumulated, electrons start to be injected to cause light to be emitted by means of the recombination with the holes. Alternatively, a photoelectric conversion element in which the current flows between the first and second electrodes by means of light irradiation onto the active layer may be configured. When the photoelectric conversion element is composed of the electronic device, in particular, a solar cell or an image sensor may be composed of the photoelectric conversion element. In this case, the voltage may not or may be applied to the control electrode, and the flowing current can be modulated by the voltage applied to the control electrode when the voltage is applied to the control electrode.

It should be understood by those skilled in the art that various modifications, combinations, sub-combinations and alterations may occur depending on design requirements and other factors insofar as they are within the scope of the appended claims or the equivalents thereof

Additionally, the present application may also be configured as below.

[1] <<Method of Manufacturing Semiconductor Device: First Aspect>>

A method of manufacturing a semiconductor device, comprising:

forming a gate electrode on a substrate;

forming a gate insulating layer of which a recessed portion is formed in a region in which a channel formation region is to be formed, on the substrate and the gate electrode;

forming the channel formation region formed of an organic semiconductor material within the recessed portion based on a coating method; and

forming source/drain electrodes on portions of the channel formation region from on the gate insulating layer.

[2] <<Method of Manufacturing Semiconductor Device: Second Aspect>>

A method of manufacturing a semiconductor device, comprising:

forming a recessed portion in a region of a base in which a channel formation region is to be formed;

forming the channel formation region formed of an organic semiconductor material within the recessed portion based on a coating method;

forming source/drain electrodes on portions of the channel formation region from on the base;

forming a gate insulating layer on the channel formation region and the source/drain electrodes; and

forming a gate electrode on the gate insulating layer on the channel formation region.

[3] The method according to [1], wherein wettability of a surface of the recessed portion of the gate insulating layer is better than wettability of a region of the gate insulating layer other than the recessed portion.

[4] The method according to [2], wherein wettability of a surface of the recessed portion of the base is better than wettability of a region of the base other than the recessed portion.

[5] The method according to any one of [1] to [4], wherein the recessed portion is formed based on a plasma etching method.

[6] <<Method of Manufacturing Image Display Device>>

A method of manufacturing an image display device comprising the method of manufacturing the semiconductor device according to any one of [1] to [5].

[7] <<Semiconductor Device: First Aspect (Bottom Gate-Top Contact Type)>>

A semiconductor device comprising:

a gate electrode formed on a substrate;

a gate insulating layer formed on the gate electrode and the substrate;

a channel formation region disposed within a recessed portion formed in the gate insulating layer and formed of an organic semiconductor material; and

source/drain electrodes formed on portions of the channel formation region from on the gate insulating layer,

wherein a top surface of the channel formation region is recessed from a boundary between the gate insulating layer and the recessed portion toward a central portion of the recessed portion.

[8]. The semiconductor device according to [7], wherein an angle between the top surface of the channel formation region and a top surface of the gate insulating layer in the boundary between the gate insulating layer and the recessed portion is 1° to 10°.

[9] <<Semiconductor Device: Second Aspect (Top Gate-Top Contact Type)>>

A semiconductor device comprising:

a channel formation region disposed within a recessed portion formed in a base and formed of an organic semiconductor material;

source/drain electrodes formed on portions of the channel formation region from on the base;

a gate insulating layer formed on the source/drain electrodes and the channel formation region; and

a gate electrode formed on the gate insulating layer,

wherein a top surface of the channel formation region is recessed from a boundary between the base and the recessed portion toward a central portion of the recessed portion.

[10] The semiconductor device according to [9], wherein an angle between the top surface of the channel formation region and a top surface of the base in the boundary between the base and the recessed portion is 1° to 10°.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A method of manufacturing a semiconductor device, comprising:
forming a gate electrode on a substrate;
forming a gate insulating layer of which a recessed portion is formed in a region in which a channel formation region is to be formed, on the substrate and the gate electrode;
forming the channel formation region formed of an organic semiconductor material within the recessed portion based on a coating method; and
forming source/drain electrodes on portions of the channel formation region from on the gate insulating layer.

2. A method of manufacturing a semiconductor device, comprising:
forming a recessed portion in a region of a base in which a channel formation region is to be formed;
forming the channel formation region formed of an organic semiconductor material within the recessed portion based on a coating method;
forming source/drain electrodes on portions of the channel formation region from on the base;
forming a gate insulating layer on the channel formation region and the source/drain electrodes; and
forming a gate electrode on the gate insulating layer on the channel formation region.

3. The method according to claim 1, wherein wettability of a surface of the recessed portion of the gate insulating layer is better than wettability of a region of the gate insulating layer other than the recessed portion.

4. The method according to claim 2, wherein wettability of a surface of the recessed portion of the base is better than wettability of a region of the base other than the recessed portion.

5. The method according to claim 1, wherein the recessed portion is formed based on a plasma etching method.

6. A method of manufacturing an image display device comprising the method of manufacturing the semiconductor device according to claim 1.

7. A semiconductor device comprising:
a gate electrode formed on a substrate;
a gate insulating layer formed on the gate electrode and the substrate;
a channel formation region disposed within a recessed portion formed in the gate insulating layer and formed of an organic semiconductor material; and
source/drain electrodes formed on portions of the channel formation region from on the gate insulating layer,
wherein a top surface of the channel formation region is recessed from a boundary between the gate insulating layer and the recessed portion toward a central portion of the recessed portion.

8. The semiconductor device according to claim 7, wherein an angle between the top surface of the channel formation region and a top surface of the gate insulating layer in the boundary between the gate insulating layer and the recessed portion is 1° to 10°.

9. A semiconductor device comprising:
a channel formation region disposed within a recessed portion formed in a base and formed of an organic semiconductor material;
source/drain electrodes formed on portions of the channel formation region from on the base;
a gate insulating layer formed on the source/drain electrodes and the channel formation region; and
a gate electrode formed on the gate insulating layer,
wherein a top surface of the channel formation region is recessed from a boundary between the base and the recessed portion toward a central portion of the recessed portion.

10. The semiconductor device according to claim 9, wherein an angle between the top surface of the channel formation region and a top surface of the base in the boundary between the base and the recessed portion is 1° to 10°.
